(19) United States
(12) Patent Application Publication
(10) Pub. No.: US 2024/0072756 A1
(43) Pub. Date: Feb. 29, 2024

(54) GUARD RING TO ENHANCE PIEZOELECTRIC COUPLING COEFFICIENT FOR BAW DEVICE

(71) Applicant: TEXAS INSTRUMENTS INCORPORATED, Dallas, TX (US)

(72) Inventors: Shaoping TANG, Allen, TX (US); Keegan MARTIN, Dallas, TX (US); Ting-Ta YEN, San Jose, CA (US)

(21) Appl. No.: 17/900,599

(22) Filed: Aug. 31, 2022

(51) Int. Cl. H03H 9/02; H03H 9/17

(52) U.S. Cl. CPC H03H 9/02015; H03H 9/171

(57) ABSTRACT

A BAW resonator includes first and second electrodes located over a substrate. A piezoelectric layer is located between the first and second electrodes. A guard ring is located between the piezoelectric layer and the second electrode, and is spaced apart from a perimeter of the electrode. The guard ring has a width in a range from 2.5 μm to 3.5 μm.

### BACKGROUND

Microelectromechanical system (MEMS) resonators are used for multiple applications, among them low-power, low-phase noise, high stability oscillators. In one example, a bulk acoustic wave (BAW) resonator is a MEMS device that includes a piezoelectric thin film sandwiched between two electrodes and is acoustically isolated from the surrounding medium. BAW resonators using piezoelectric films with thicknesses ranging from several micrometers down to tenths of micrometers resonate in the frequency range of roughly 100 MHz to 10 GHz.

### SUMMARY

One example provides a method of forming a bulk acoustic wave (BAW) resonator. The method includes forming a lower acoustic reflector over a substrate, the lower acoustic reflector including alternating dielectric layers of lower and higher acoustic impedance materials. A piezoelectric layer is formed over the lower acoustic reflector, and an upper acoustic reflector also including alternating dielectric layers of lower and higher acoustic impedance materials is formed over the piezoelectric layer. A metal guard ring is formed between the piezoelectric layer and the upper acoustic reflector, the guard ring having a width no greater than 3.5 μm.

Another example provides a BAW resonator. The BAW resonator includes first and second electrodes located over a substrate. A piezoelectric layer is located between the first and second electrodes. A guard ring is located between the piezoelectric layer and the second electrode, and is spaced apart from a perimeter of the electrode. The guard ring has a width in a range from 2.5 μm to 3.5 μm.

### BRIEF DESCRIPTION OF THE DRAWINGS

For a detailed description of various examples, reference will now be made to the accompanying drawings in which:

FIG. 1 is a plot illustrating impedance as a function of frequency, corresponding to operation of an example BAW resonator (i.e., a MEMS acoustic wave resonator) shown in FIG. 2.

FIG. 2 is a cross-sectional view of an illustrative BAW resonator having a guard ring in accordance with an example.

FIG. 3. is a cross-sectional view of the illustrative BAW resonator shown in FIG. 2, taken along line 3-3 of FIG. 2.

FIG. 4 is a flowchart illustrating a method for manufacturing a BAW resonator in accordance with an example.

FIG. 5 is a plot illustrating Qₚ and fₚ−fₛ and as a function of guard ring width for a BAW resonator in accordance with an example.

The same reference number is used in the drawings for the same or similar (either by function and/or structure) features.

### DETAILED DESCRIPTION

Various methods and devices of the present disclosure may beneficially provide acoustic resonators, e.g. BAW resonators, with decreased coupling between series and parallel resonant modes, as evidenced by a larger figure of merit (FOM) as described herein. While such reduced coupling is expected to favorably increase the end-of-line yield of such resonators by ensuring the coupling coefficient exceeds a threshold value determined to meet the needs of products and devices employing the acoustic resonators, no particular result is a requirement unless explicitly recited in a particular claim.

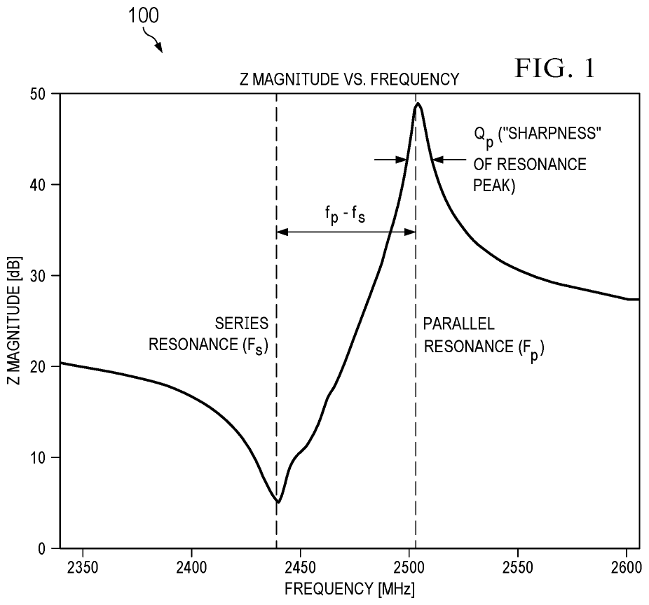

FIG. 1 shows a frequency response plot 100 (frequency along the x-axis) of the impedance (Z, vertical axis) of an illustrative BAW resonator. A resonator may have a series resonance frequency fₛ corresponding to the frequency of a series resonance, and fₚ corresponding to the frequency of a parallel resonance. The frequency fₚ is the frequency corresponding to the maximum impedance, which is at a natural resonant frequency of the resonator. The frequency fₛ is the frequency corresponding to the lowest impedance of the resonator. The BAW resonator piezo-electrically oscillates when supplied with a time-varying electrical signal in an operational frequency range. If the frequency of the input electrical signal is at or close to the parallel resonant frequency fₚ, the magnitude of the oscillation is larger than at other frequencies. At fₛ, the amount of mechanical vibration is very small. A coupling coefficient (referred to as k_{eff}²) is related to fₚ and fₛ and is a measure of efficiency of the energy transfer from the input electrical signal to the resulting piezoelectric vibration. The coupling coefficient is a dimensionless parameter that scales across different frequencies, and which is representative of the level of separation between fₛ and fₚ. In general, a higher value of the coupling coefficient is desirable for the operation of a BAW resonator.

When using a BAW resonator in at least some applications (e.g., an oscillator circuit), fₚ and fₛ should be spaced apart as much as possible. One reason for a larger spacing between fₚ and fₛ is to be able to accommodate a wide range of possible fₚ frequencies without becoming so close to fₛ to make the resonator unusable due to energy loss mechanisms. Further, phase noise or jitter may increase if fₛ is too close to fₚ. The coupling coefficient may be affected by piezoelectric layer quality, electrode configuration, acoustic reflector, and parasitic parameters.

If the frequency separation between fₛ and fₚ is too small, too much energy may be lost by the resonator and the device may not work. With resonators that have fₚ and fₛ, at the frequency fₚ the device will have a very sharp increase in magnitude of impedance (see FIG. 1), at which frequency the circuit appears as an open, or low-loss capacitance, at resonance frequency. Conversely, at the series resonance fₛ, the device will have a low impedance magnitude and will behave primarily resistively and may approximate a short. Typically, the emphasis on fₛ or fₚ is dependent on the particular oscillator or filter applications desired. The response of the resonator is a function of frequency. The resonator achieves maximum resonance at fₚ and thus it is generally desirable to operate the resonator at or near fₚ. When fₛ is too close to fₚ product performance may be negatively affected due to increased phase noise and jitter, and decreases pulling range. Qₚ is a parameter that characterizes the sharpness of the frequency response near the parallel resonant frequency, fₚ. A higher Qp value means a narrower bandwidth of the frequency response near fₚ, and a smaller Qp means a broader bandwidth.

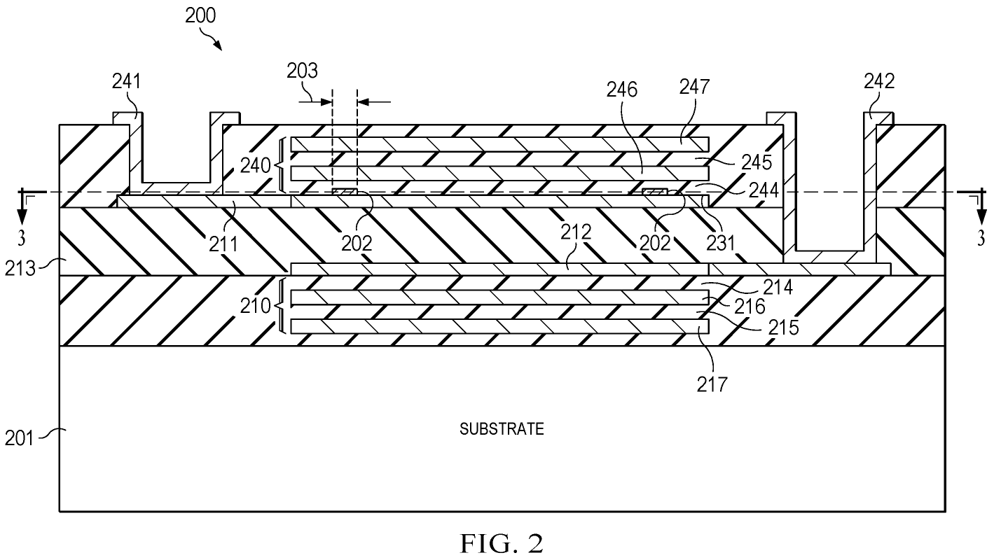

When the input AC signal is at or near fₚ, a piezoelectric layer (see FIG. 2, discussed more fully below) physically displaces in the vertical axis by, for example, a few angstroms, with the maximum physical displacement desired for a given electrical signal. Ideally, vertical displacement is only exhibited with no lateral displacement, and thus, most or all of the input energy is used for the intended mechanical response of the resonator. In this scenario, Qₚ will be a higher value and thus the frequency response of the resonator will have a shaper/narrower shape near fₚ. Increasing both Qₚ and k_{eff}² is desired to achieve a higher performance BAW. The guard ring as described herein results in the quality factor Qₚ being relatively large while the difference between fₛ and fₚ also being relatively large.

The embodiments of a BAW resonator described herein achieve a relatively high coupling coefficient through the use of a guard ring as described herein. A guard ring is a acoustic-reflective structure formed around a perimeter of an active region of the resonator corresponding to an overlap of the first electrode, piezoelectric layer, and second electrode. A guard ring can be formed adjacent to a top and/or bottom electrode of the BAW resonator. In general, the presence of the guard ring can improve performance of the BAW resonator by suppressing the excitation of spurious and/or lossy modes of operation such as lateral acoustic wave energy loss. BAW resonators diverge from their ideal behavior due to these spurious modes that cause high loss regimes throughout their operating frequency range. Typically, control of BAW resonators is constrained to unidirectional power flow at each resonant cycle for maximum efficiency operation. However, output power depends on the frequency with such control, which means the BAW resonator cannot operate at loads corresponding to spurious mode frequencies. In other words, spurious modes limit the BAW resonator's operating range. A guard ring suppresses at least some of those spurious modes, thereby reducing loss paths. As such, the BAW resonator described herein includes a guard ring that is effective in increasing the coupling coefficient of the resonator (relative to other BAW resonators). Compared to existing processes, the guard ring described herein can increase (e.g., by approximately 15%) the coupling coefficient of the resonator while keeping other BAW resonator parameters (such as layer quality, thickness, electrode configuration) relatively unchanged. Thus, existing BAW resonator designs may be used with the guard ring described herein.

The BAW resonator described herein has several beneficial operating characteristics. For example, the piezoelectric coupling coefficient of a BAW resonator has a monotonic relationship with guard ring width. This relationship is advantageous because the guard ring width can be independently controlled to increase the coupling coefficient while keeping the other BAW resonator parameters mentioned above relatively unchanged. For a given resonant frequency, the BAW resonator having the guard ring described herein achieves a satisfactorily high quality factor (Qₚ) and coupling coefficient (k_{eff}²). By optimizing the k_{eff}², a larger offset between fₚ and fₛ is observed. As a result, an increase in pulling range is achieved. Pulling range is a measure of how much a resonator's frequency can deviate from the target frequency, and then still be tuned back to the target frequency. The larger the pulling range the better, as a larger pulling range will allow for wider process variation of the resonator's frequency, which enables a lower cost and more manufacturable device.

Referring again to FIG. 1 the frequency plot 100 illustrates impedance magnitude (Z, given in logarithmic form) as a function of frequency for a BAW resonator. Both fₚ and fₛ are graphically illustrated in FIG. 1. The piezoelectric coupling coefficient k_{eff}² is a function of fₚ−fₛ. More specifically, the k_{eff}² value is important for device performance, with a larger value resulting in better performance. k_{eff}² is typically proportional to the difference between fₚ and fₛ. The calculation of k_{eff}² via series resonant frequency (fₛ) and parallel resonant frequency (fₚ) is expressed as

$${k}_{eff}^{2} = \frac{{π}^{2}}{4} \frac{( {f}_{p} - {f}_{s} )}{{f}_{s}} .$$

Without implied limitation, k_{eff}² if may be 0.035-0.041.

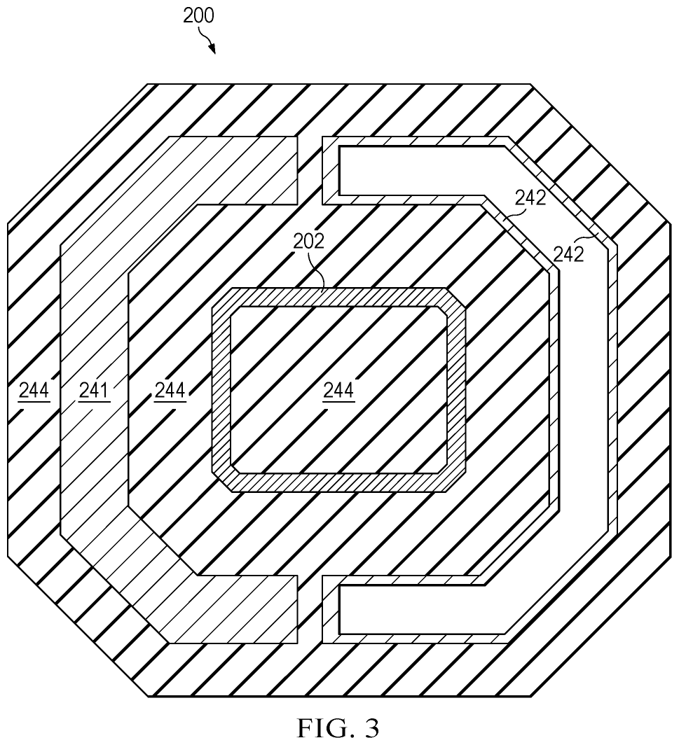

FIG. 2 is a cross-sectional view of an illustrative BAW resonator 200 having a guard ring 202, including guard ring width 203, that is placed above a perimeter of upper electrode 211 with a recessed space 231 to the edge of the electrode 211. FIG. 3 is a cross-sectional view of the illustrative BAW resonator 200 shown in FIG. 2, taken along section line 3-3 of FIG. 2. With reference to FIG. 2, BAW resonator 200 includes an upper electrode 211 and a lower electrode 212, which are separated by a piezoelectric layer 213. BAW resonator 200 may be fabricated over substrate 201 using known or later developed semiconductor fabrication techniques.

In this example, BAW resonator 200 is a solidly mounted resonator that uses an acoustic reflector 210 between the lower electrode 212 and the substrate 201 to insulate acoustic energy from leaking from the resonator into the substrate 201. A second acoustic reflector 240 is disposed on a side of the upper electrode opposite the piezoelectric layer 213 to also prevent acoustic energy from leaking vertically from the top of BAW resonator 200. In some examples, an additional acoustic reflector may be positioned on the sides of upper electrode 211.

In this example, electrodes 211, 212 and guard ring 202 are patterned from layers of metal, such as aluminum (Al), molybdenum (Mo), copper (Cu), gold (Au), aluminum copper (AlCu, e.g. 1% Cu), and/or combinations thereof. The guard ring 202 may be below or above the electrode 211, and may touch the electrode 211. Similarly the guard ring 202 may be below or above the electrode 212, and may touch the electrode 212. The guard ring may run parallel to a perimeter of the electrode 211 and/or the electrode 212, and may be inset from the edge of one or both of the electrodes 211 and 212 such that the perimeter of one or both of the electrodes 211 and 212 circumscribes and is spaced apart from the guard ring 202. Similarly, a lateral perimeter of one or both of the acoustic reflectors 210 and 240 may circumscribe and be spaced apart from the guard ring 202.

The thickness of the guard ring may be any value generally consistent with semiconductor interconnect metal levels, e.g. 50 nm to 800 nm. In one specific example the guard ring having a thickness of about 90-100 nm has been determined to provide beneficial results. Piezoelectric layer 213 may be fabricated using various piezo materials, such as aluminum nitride (AlN), quartz, gallium nitride (GaN), zinc oxide (ZnO), PZT, lithium niobate, etc. A temperature-compensating layer of oxide (not shown) may be located between the upper electrode 211 and the piezoelectric layer 213. Electrical contacts 241, 242 may be metal contacts and are in contact with upper electrode 211 and lower electrode 212, respectively, and thereby provide contacts for coupling BAW resonator 200 to an external oscillator circuit.

In this example, acoustic reflectors 210, 240 are distributed Bragg reflector (DBR) structures. A DBR is a structure formed from multiple layers of alternating materials with varying acoustic impedance. Each layer boundary causes a partial reflection of an acoustic wave. For bulk acoustic waves whose wavelength is approximately four times the thickness of each layer, the many reflections combine with constructive interference, and the layers act as a high-quality reflector, or mirror, for wavelengths in that range. Any known or later developed Bragg mirror, dielectric mirror, acoustic reflector, etc. may be used to implement the acoustic reflectors 210, 240. In one example, acoustic reflector 210 includes: (a) alternating flat conductive members (e.g., layers, sheets, plates, etc. of metal), two of which are designated by reference numbers 216 and 217; and (b) flat dielectric members (e.g., layers, sheets, plates, etc. of a dielectric material), two of which are designated by reference numbers 214 and 215. The thicknesses of, and distances between, the conductive members 216 and 217 are selected based on an intended resonance frequency of the BAW resonator 200. As a result, the acoustic reflector 210 reduces spurious modes, and it confines (such as by reflecting, directing, containing, etc.) acoustic energy of the main mode at that frequency in piezoelectric layer 213 and the two electrodes 211 and 212 which together act as a resonant cavity of the BAW resonator 200. In some examples, confining main mode acoustic energy refers to confining a portion of the main mode of acoustic energy. In this manner, the quality factor (Q) of the BAW resonator 200 is increased and, in turn, the performance of a system including the example BAW resonator 200 is improved. In some examples, the conductive members 216, 217 are formed by tungsten (W), titanium tungsten (TiW) or copper (Cu). In some examples, the dielectric members 214, 215 area formed by silicon dioxide (SiO₂), or a carbon-doped oxide dielectric (such as SiCOH), or aluminum nitride (AlN). In some examples, the acoustic reflector 210 may be implemented using a two-dimensional (2D) or a three-dimensional phononic crystal. Bottom electrode 212 may be formed in contact with the adjacent Bragg mirror 210. Acoustic reflector 240, including its members 244, 245, 246, 247, is similar in structure and function to that of acoustic reflector 210. For example, acoustic reflector 240 includes alternating flat conductive members 246, 247 and flat dielectric members 244, 245. In further examples, either or both of the acoustic reflectors 210, 240 may have more than two metal layers.

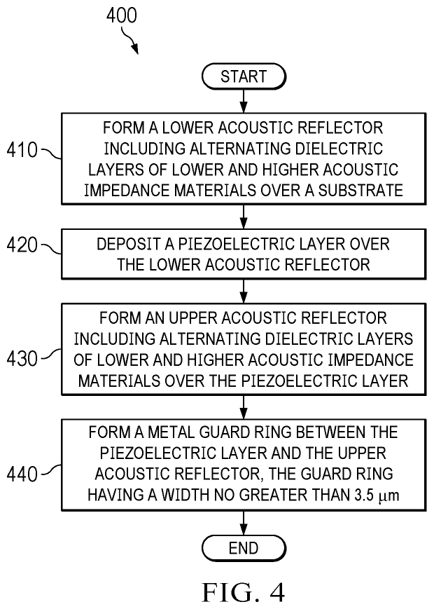

With reference to FIG. 4, in another example, a method 400 for manufacturing a BAW resonator includes at 410 forming a lower acoustic reflector including alternating dielectric layers of lower and higher acoustic impedance materials over a substrate. At 420 a piezoelectric layer is formed over the lower acoustic reflector. At 430 an upper acoustic reflector is formed that includes alternating dielectric layers of lower and higher acoustic impedance materials over the piezoelectric layer. And at 440 a metal guard ring is formed between the piezoelectric layer and the upper acoustic reflector, the guard ring having a width no greater than 3.5 μm.

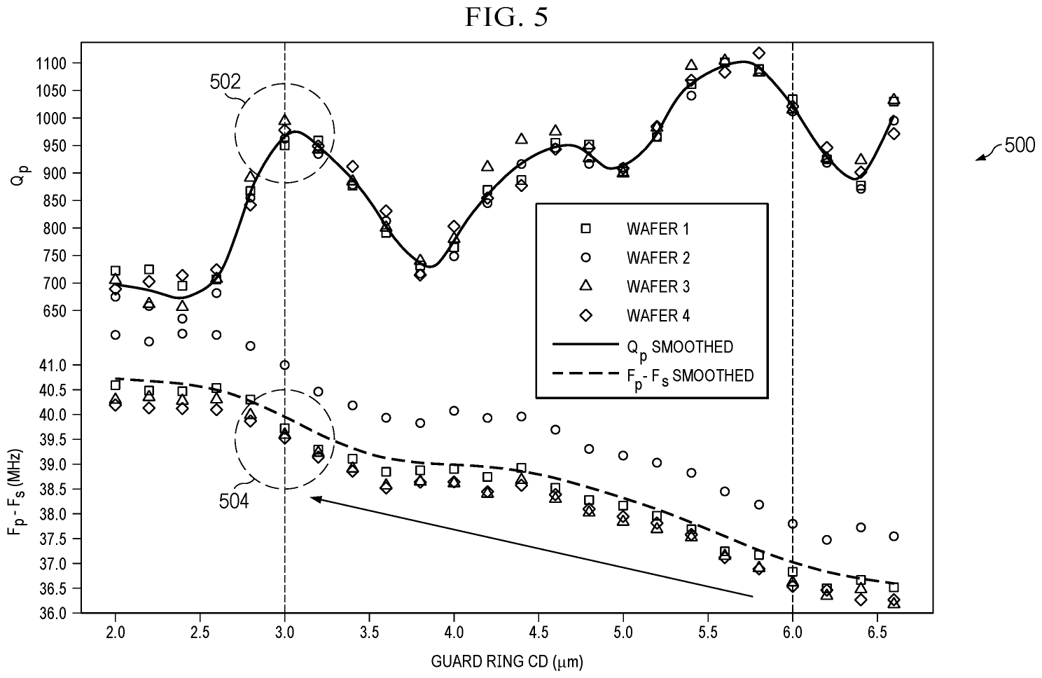

FIG. 5 is a plot 500 illustrating fₚ−fₛ and Qₚ as a function of guard ring width for a BAW resonator. The Qₚ characteristic represents quality factor of the parallel resonance peak impedance and, and the fₚ−fₛ characteristic is a proxy for k_{eff}² . As illustrated in FIG. 5, both Qₚ and k_{eff}² respond to guard ring width in an ordered way, e.g., Qₚ responds in a periodic manner (along with a 2nd-order linear increase, in this example) and k_{eff}² responds in a monotonic manner, thereby providing a basis for selecting a guard ring line width that beneficially increases the frequency margin of operation. Since both greater Qₚ and greater separation of fₚ and fₛ are desirable attributes a FOM that is a function of both of these characteristics may be a useful guide to determining a favorable guard ring width. The FOM used in this work is the product of Qₚ and k_{eff}² , thus FOM=Qₚ×k_{eff}². Inspection of FIG. 5 indicates that a favorable FOM may result at a guard ring width near a local maximum of Qₚ. In this particular example, local maxima occur at a guard ring width of about 3 μm, 4.5 μm and 5.5 μm. While Qₚ is greater at 5.5 μm than at 3 μm, the FOM is greater at 3 μm due to the greater separation of fₚ and fₛ at this guard ring width. Indeed, calculation of the FOM results in a value about 12% greater at 3 μm than at 5.5 μm. The favorable guard ring width may be viewed is a function of the resonant frequency and of the acoustic velocity piezoelectric layer 213 (FIG. 2), the latter being a known material characteristic for a given piezoelectric layer film. In some examples an FOM in a range from about 3.5E4 to about 4.3E4 is expected to result in significant increase of operating frequency margin, which may also result in a significant improvement of device yield.

In an example, a method of determining a guard ring width for a BAW resonator as described herein includes:
Determining two input values of the resonator:
   Frequency of parallel resonance (fₚ) of the resonator
   Acoustic velocity of the piezoelectric layer of the resonator
   These parameters are variables that may generally change, depending on the exact acoustic resonator, and will determine the period of acoustic reflection for that resonator.
Then determine wavelength from above using the following formula:

λ=v/fₚ,
where:
   λ is the wavelength of the acoustic wave
   v is the acoustic velocity of the piezoelectric layer
   fₚ is the parallel resonance of the resonator.
The Qₚ of the resonator will then have a local maximum and minimum at a guard ring width at a period equal to λ/4. This means that maximum Qₚ can be observed as the guard ring width changes in increments of λ/2. These half-λ increments, then, are expected to provide favorable guard ring geometries widths when optimizing the Qₚ parameter.
k_{eff}² linearly increases with respect to decreasing guard ring width. A smaller guard ring width then is favorable when optimizing the k_{eff}² parameter.
The minimum width of the guard ring may be equal to λ/4.
A favorable guard ring width is determined to be the width at which the FOM has a global maximum value within the operating frequency range of interest. The value of the FOM in determining the favorable guard ring width is based in part by the heretofore unknown recognition that Qₚ and k_{eff}² act in concert to result in a meaningful FOM (e.g. periodic local maxima of Qₚ and monotonic k_{eff}²). This behavior is not known to exist in conventional acoustic resonators, or is at least rare.
   The favorable width of the guard ring may then be determined empirically or through simulation by varying the width of the guard ring.
With this information, the guard ring width then be selected on any given acoustic resonator for the two known input values fₚ and v.

More specifically, the process to design a BAW resonator as described herein includes determining the intended operating frequency (e.g., 2.4-2.6 GHz) of the BAW resonator, and acoustic velocity of the piezoelectric film (which may be AlN or another suitable piezoelectric material). Next, the wavelength of the lateral acoustic wave is calculated. And, as shown in FIG. 5, the periodicity of the Qₚ characteristic is illustrated. These will be the favorable Qₚ points, i.e., frequencies having locally maximum reflection. Then, the BAW resonator (having a given target operating frequency) is designed to have a certain guard ring width in order to achieve a high combination of Qₚ and coupling coefficient (or fₚ−fₛ). The values of Qₚ and k_{eff}² can be generated either through simulation or empirically determined.

Past innovations included adding a guard ring to a BAW resonator analogous to that illustrated in FIGS. 2 and 3 based on the then-recognition that by spacing a guard ring away from the perimeter edge of the top electrode, ripple and spurious modes around fₚ can be significantly suppressed, at least in part lowering the cut-off frequency of the resonator to fulfill the boundary condition required to have piston mode operation. See U.S. Pat. No. 11,394,361, incorporated herein by reference in its entirety. In the present disclosure, it is recognized that while the previously described guard ring results in significant improvement of device performance by reduction of such spurious modes, the frequency difference fₚ−fₛ may remain small enough that vibrational energy may couple from the parallel resonant mode to the series resonant mode, negatively affecting device performance. In view of the deficiency of such prior solutions, the present disclosure newly recognizes that the FOM described above provides a quantitative tool to inform significant refinement of the guard ring width resulting in a valuable increase of device yield.

Given the target operating frequency of the BAW resonator and the acoustic velocity of an acoustic wave transmitted in the piezoelectric material (in one example, AlN), the range of the guard ring width 203 (see FIG. 2) may be 3 μm±0.5 μm. This width range provides relatively large value of fₚ−fₛ, though Qₚ may be lower than desirable at the limits of the range. In some examples the guard ring width 203 may be 3 μm±0.25 μm, or in examples for which a value of Qₚ is desired to be at or near the local maximum value the guard ring width 203 may be 3 μm±0.1 μm. In some cases it may be beneficial to limit the guard ring width 203 to no less than 2.5 μm and no greater than 3.5 μm in the illustrated example, as otherwise the value of fₚ−fₛ and/or Qₚ may be too low to provide a beneficial FOM, as described further below. The device may be operating at a frequency range of 2.4-2.6 GHz and, more specifically, approximately 2.5 GHz. With these two parameters, the acoustic wavelength λₐ of the piezoelectric layer 213 can be determined. The guard ring width 203 should then be λₐ/4. In one example, Qₚ is 900-1,050 (taken from the local maximum at 502 depicted in FIG. 5) and fₚ−fₛ is 39-40.5 MHz (taken from the same abscissa as the local maximum of Qₚ in FIG. 5). To achieve high FOM (Qₚ*k_{eff}²), one can select a guard ring width of 3.0 μm, for example, which corresponds to a local Qₚ peak of ˜950 while fₚ−fₛ is relatively high compared to a guard ring width of 6.0 μm. In various examples the thickness of the guard ring is about 400 nm. It has been observed that the guard ring thickness has negligible effect on the guard ring width as determined above in a thickness range off 200 nm to 600 nm. Thus the FOM is not expected to be significantly sensitive to typical process variation of thickness of the metal layer from which the guard ring is formed.

Note that the value of Qp at a guard ring width of 3 μm is about 10% less than the value of Qp at about 5.5 μm. In spite of this reduction of Qp at the smaller guard ring width, the value of the FOM is greater at 3 μm than at 6 μm. It is expected that even if a designer recognized the variation of Qp with guard ring width, a guard ring width would be selected that maximizes Qp. In contrast, examples consistent with the disclosure may select a Qp that is less than a maximum Qp such that the FOM is locally maximized rather than Qp being maximized.

Thus, for a given input operating frequency (of the entire device) and acoustic velocity of the piezoelectric film itself, the BAW resonator described herein employs a guard ring design (i.e., width) that achieves a combination of Qₚ and k_{eff}² that is higher than in other BAW resonators, thereby resulting in an improved, higher performance BAW resonator having a high coupling coefficient.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Unless otherwise stated, “about,” “approximately,” or “substantially” preceding a value means +/−10 percent of the stated value. Modifications are possible in the described examples, and other examples are possible within the scope of the claims.

Modifications are possible in the described embodiments, and other embodiments are possible, within the scope of the claims.

What is claimed is:

1. A method of forming a bulk acoustic wave (BAW) resonator, comprising:
forming a lower acoustic reflector including alternating dielectric layers of lower and higher acoustic impedance materials over a substrate;
depositing a piezoelectric layer over the lower acoustic reflector;
forming an upper acoustic reflector including alternating dielectric layers of lower and higher acoustic impedance materials over the piezoelectric layer; and
forming a metal guard ring between the piezoelectric layer and the upper acoustic reflector, the guard ring having a width no greater than 3.5 μm.

2. The method of claim 1, further comprising forming an electrode over the piezoelectric layer, the metal guard ring located between the electrode and the upper acoustic reflector.

3. The method of claim 1, wherein the guard ring has a width no less than 2.5 μm.

4. The method of claim 1, wherein the piezoelectric layer has a thickness of about 700 nm.

5. The method of claim 1, wherein the resonator has a fundamental resonant frequency of about 2.5 GHz.

6. The method of claim 1, wherein the width of the guard ring is located at about a local maximum of a characteristic of a quality factor of the BAW resonator as a function of guard ring width.

7. The method of claim 1, wherein the BAW resonator exhibits a quality factor (Qₚ) in a range from 900 to 1,050.

8. The method of claim 1, wherein the BAW resonator exhibits a parallel resonance frequency (fₚ) and a series resonance frequency (fₛ), and wherein fₚ−fₛ is in a range from 39 MHz to 40.5 MHz

9. The method of claim 1, wherein the BAW resonator is configured to operate at an input operating frequency in a range from 2.4 GHz to 2.6 GHz.

10. The method of claim 1, wherein the piezoelectric layer comprises AlN.

11. A BAW resonator, comprising:
lower and upper electrodes over a substrate;
a piezoelectric layer between the lower and upper electrodes; and
a metal guard ring between the piezoelectric layer and the second electrode, wherein the guard ring has a width in a range from 2.5 μm to 3.5 μm.

12. The BAW resonator of claim 11, wherein the BAW resonator exhibits a quality factor (Qₚ) of 900-1,050.

13. The BAW resonator of claim 11, wherein the BAW resonator exhibits a parallel resonance frequency (fₚ) and a series resonance frequency (fₛ), and wherein fₚ−fₛ is 39-40.5 MHz.

14. The BAW resonator of claim 11, wherein the BAW resonator exhibits a parallel resonance frequency (fₚ), a series resonance frequency (fₛ), and a coupling coefficient (k_{eff}²) calculated as
$${k}_{e f f}^{2} = \frac{{π}^{2}}{4} \frac{( {f}_{p} - {f}_{s} )}{{f}_{s}} ,$$
and wherein k_{eff}²=0.035-0.041.

15. The BAW resonator of claim 11, wherein the BAW resonator exhibits a quality factor (Qₚ), a parallel resonance frequency (fₚ), and a series resonance frequency (fₛ), wherein the guard ring width is further based on a Figure of Merit (FOM) of the BAW resonator determined as the product of Qₚ and a coupling coefficient k_{eff}² if determined as
$${k}_{e f f}^{2} = \frac{{π}^{2}}{4} \frac{( {f}_{p} - {f}_{s} )}{{f}_{s}} ,$$
wherein the FOM is in a range from 3.5E4 to 4.2E4.

16. The BAW resonator of claim 11, wherein the BAW resonator operates at an input operating frequency of 2.4-2.6 GHz.

17. The BAW resonator of claim 11, wherein the piezoelectric layer comprises AlN.

18. The BAW resonator of claim 11, wherein the guard ring comprises AlCu.

19. The BAW resonator of claim 11, wherein the metal guard ring touches the upper electrode.

20. The BAW resonator of claim 11, wherein the resonator has a fundamental resonant frequency of about 2.5 GHz.
